(19) United States
(12) Patent Application Publication
(10) Pub. No.: US 2026/0143808 A1
(43) Pub. Date: May 21, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Wen-Kai Lin, Tainan City (TW); Yao-Jhan Wang, Tainan City (TW); Sheng-Yuan Hsueh, Tainan City (TW); Kuo-Hsing Lee, Hsinchu County (TW); Chih-Kai Kang, Tainan City (TW); Yung-Chen Chiu, Taichung City (TW); Guan-Kai Huang, Tainan City (TW)

(73) Assignee: UNITED MICROELECTRONICS CORP., Hsin-Chu City (TW)

(21) Appl. No.: 18/981,633

(22) Filed: Dec. 15, 2024

(30) Foreign Application Priority Data
Nov. 18, 2024 (TW) 113144217

(51) Int. Cl. H10D 84/85; H10D 84/01

(52) U.S. Cl. CPC H10D 84/856; H10D 84/0179; H10D 84/0188; H10D 84/0193; H10D 84/853

(57) ABSTRACT

A semiconductor device includes a substrate having a non-planar device region and a planar device region, a first isolation structure in the substrate of the planar device region, a first gate structure on the first isolation structure, a first epitaxial layer adjacent to the first gate structure, a second isolation structure in the substrate of the non-planar device region, a second gate structure on the second isolation structure, and a second epitaxial layer adjacent to the second gate structure. Preferably, the first gate structure includes a first metal gate and the second gate structure includes a second metal gate.

### BACKGROUND OF THE INVENTION

### 1. FIELD OF THE INVENTION

The invention relates to a method for fabricating semiconductor device, and more

particularly to a method of forming isolation structures on non-planar device region and planar device region.

### 2. DESCRIPTION OF THE PRIOR ART

In current semiconductor processing, controllers, memories, circuits of low-voltage operation and power devices of high-voltage operation are largely integrated into a single chip to achieve a single-chip system. The power device or high-voltage (HV) device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease the integration of high-voltage devices and FinFET devices start to face numerous challenges such as current leakage and control of breakdown voltage. Hence, how to improve the current fabrication for improving performance of the device has become an important task in this field.

### SUMMARY OF THE INVENTION

According to an embodiment of the present invention, a semiconductor device includes a substrate having a non-planar device region and a planar device region, a first isolation structure in the substrate of the planar device region, a first gate structure on the first isolation structure, a first epitaxial layer adjacent to the first gate structure, a second isolation structure in the substrate of the non-planar device region, a second gate structure on the second isolation structure, and a second epitaxial layer adjacent to the second gate structure. Preferably, the first gate structure includes a first metal gate and the second gate structure includes a second metal gate.

According to another aspect of the present invention, a semiconductor device includes a substrate having a non-planar device region and a planar device region, a first isolation structure in the substrate of the planar device region, a first gate structure on the first isolation structure, and first epitaxial layer adjacent to the first gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a semiconductor device according to an embodiment of the present invention.

FIG. 9 illustrates a top view of the semiconductor device on the planar device region according to an embodiment of the present invention.

### DETAILED DESCRIPTION

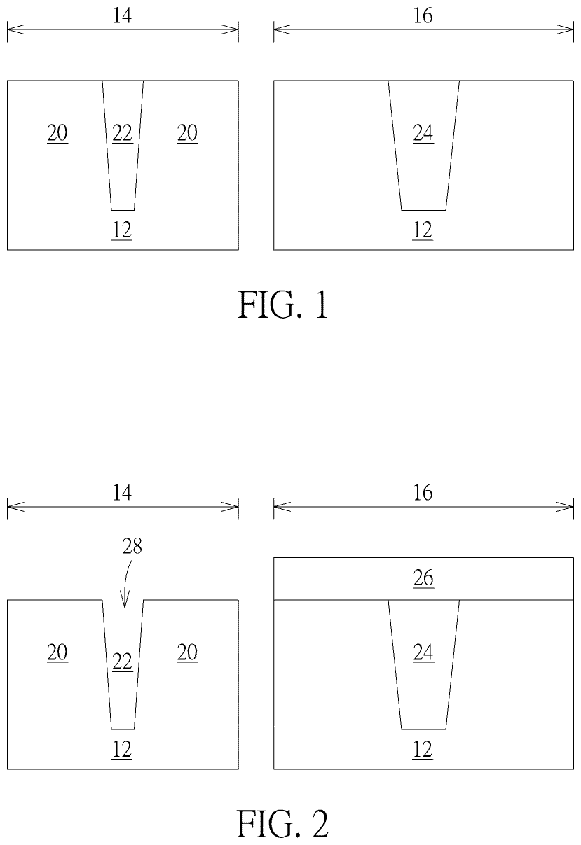

Referring to FIGS. 1-8, FIGS. 1-8 illustrate a method for fabricating a semiconductor device according to an embodiment of the present invention. As shown in FIG. 1, a substrate 12, such as a silicon substrate or silicon-on-insulator (SOI) substrate is provided and a non-planar device region 14 and a planar device region 16 are defined on the substrate 12, in which the non-planar device region 14 could be used for fabricating digital devices while the planar device region 16 could be used for fabricating analog devices. In this embodiment, the non-planar device region 14 and the planar device region 16 could be transistor regions having same conductive type or different conductive types. For instance, each of the two regions 14, 16 could be a PMOS region or a NMOS region and the two regions 14 and 16 are defined to fabricate gate structures having different threshold voltages in the later process. Preferably, it would be desirable to first conduct an implantation process to form p-type deep wells on the planar device region 16 and a n-type deep well on the non-planar device region 14, but not limited thereto.

Next, a plurality of fin-shaped structures 20 are formed on the substrate 12 of the non-planar device region 14. According to an embodiment of the present invention, the fin-shaped structures 14 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 20 could also be obtained by first forming a patterned mask (not shown) on the substrate, 12, and through an etching process, the pattern of the patterned mask is transferred to the substrate 12 to form the fin-shaped structures 20. Moreover, the formation of the fin-shaped structures 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding the fin-shaped structures 20. These approaches for forming the fin-shaped structures 20 are all within the scope of the present invention. According to an embodiment of the present invention, one or more liner and/or hard mask could be formed on the top surface of the fin-shaped structures 20 during the above patterning process, in which the liner and hard mask could include silicon oxide (SiO₂) or silicon nitride (SiN), but not limited thereto.

Next, isolation structures 22, 24 could be formed around the fin-shaped structures 20 on the non-planar device region 14 and in the substrate 12 of the planar device region 16. In this embodiment, the formation of the isolation structures 22, 24 could be accomplished by first forming a patterned mask (not shown) on the substrate 12 and then conducting an etching process by using the patterned mask as mask to remove part of the fin-shaped structures 20 and/or part of the substrate 12 to form trenches (not shown), in which the trench could separate each of the fin-shaped structures 20 on the non-planar device region 14 in to two parts. Next, an insulating layer made of silicon oxide could be formed to fill the trenches and then a planarizing process such as chemical mechanical polishing (CMP) process is conducted to remove part of the insulating layer so that the top surface of the remaining insulating layer is even with the top surface of the fin-shaped structures 20 or substrate 12 to form isolation structures 22, 24. It should be noted that since a single gate structures is to be formed on top of each of the isolation structures 22, 24 in the later process for dividing diffusion regions such as source/drain regions adjacent to two sides of the gate structure, each of the isolation structures 22, 24 is also referred to as a single diffusion break (SDB).

Next, as shown in FIG. 2, a patterned mask 26 such as patterned resist is formed to cover the substrate 12 and isolation structure 24 on the planar device region 16 and then an etching process is conducted by using the patterned mask 26 as mask to remove part of the isolation structure 22 on the non-planar device region 14 for forming a recess 28 so that the top surface of the remaining isolation structure 22 is slightly lower than the top surface of the fin-shaped structures 20 on two adjacent sides.

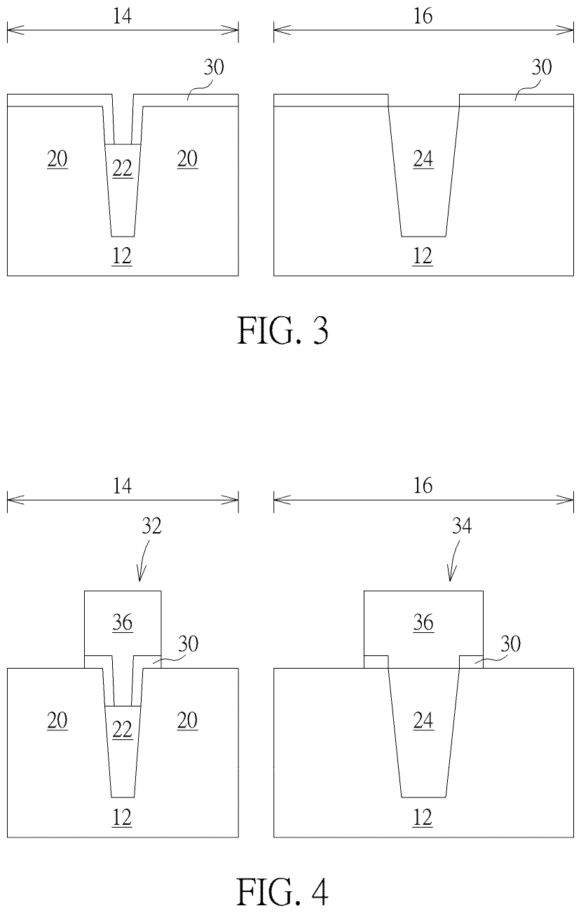

Next, as shown in FIG. 3, after stripping the patterned mask 26, a thermal oxidation process could be conducted to form a gate dielectric layer 30 made of silicon oxide on the substrate 12 on both non-planar device region 14 and planar device region 16, in which the gate dielectric layer 30 on the non-planar device region 14 preferably covers the top surface and sidewalls of the fin-shaped structures 20 adjacent to two sides of the isolation structure 22. The gate dielectric layer 30 on the planar device region 16 on the other hand is disposed on the surface of the substrate 12 adjacent two sides of the isolation structure 24. According to an embodiment of the present invention, the thickness of the gate dielectric layer 30 formed at this stage is between 27-33 Angstroms or most preferably 30 Angstroms.

Next, as shown in FIG. 4, gate structures 32, 34 or dummy gates could be formed on the fin-shaped structures 20 and substrate 12 on both non-planar device region 14 and planar device region 16. In this embodiment, the formation of the gate structures 32, 34 could be accomplished by a gate first process, a high-k first approach from gate last process, or a high-k last approach from gate last process. Since this embodiment pertains to a high-k last approach, a gate material layer 36 made of polysilicon and a selective hard mask (not shown) could be formed sequentially on the substrate 12 or gate dielectric layer 30, and a photo-etching process is then conducted by using a patterned resist (not shown) as mask to remove part of the gate material layer 36 and part of the gate dielectric layer 30 through single or multiple etching processes. After stripping the patterned resist, gate structures 32, 34 each made of a patterned gate dielectric layer 30 and a patterned material layer 36 are formed on the substrate 12, in which the patterned gate material layer 36 could be serving as gate electrodes in each region.

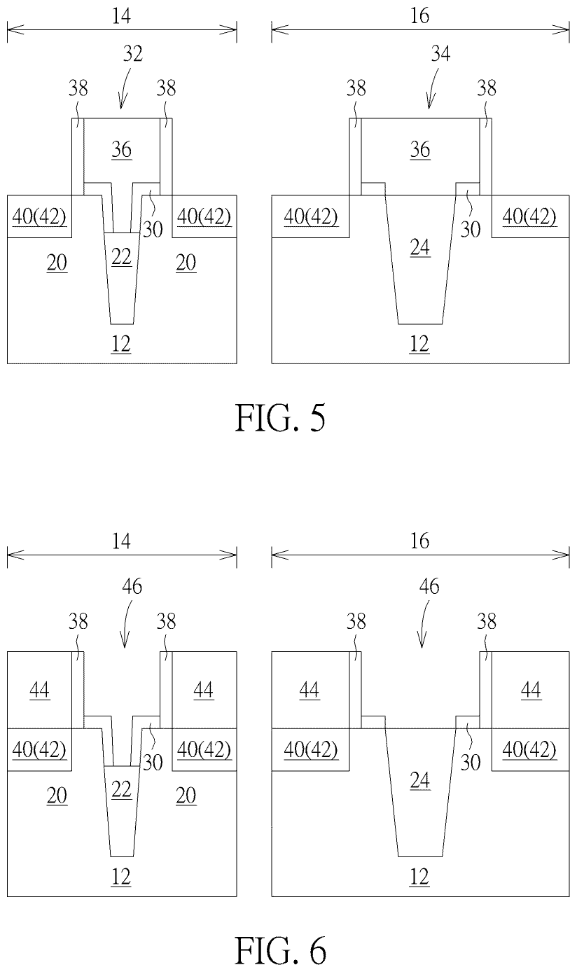

Next, as shown in FIG. 5, at least a spacer 38 is formed on the sidewalls of each of the gate structures 32, 34 and then epitaxial layers 40 are formed in the fin-shaped structures 20 and substrate 12 adjacent to two sides of the gate structures 32, 34. Preferably, the formation of the epitaxial layers 40 could be accomplished by first using a photo-etching process to remove part of the substrate 12 adjacent to the gate structures 32, 34 for forming recesses (not shown) and then conducing a selective epitaxial growth (SEG) process to form epitaxial layers 40 in the recesses. In this embodiment, each of the spacers 38 could be a single spacer or a composite spacer, the spacers 38 could be made of same or different materials, and the spacers 38 could include SiO₂, SiN, SiON, SiCN, or combination thereof.

According to an embodiment of the present invention, the epitaxial layers 40 could also be formed to include different materials depending on the type of transistor being fabricated. For instance, if the MOS transistor being fabricated were to be a PMOS transistor, the epitaxial layers 40 could be made of material including but not limited to for example SiGe, SiGeB, or SiGeSn. If the MOS transistor being fabricated were to be a NMOS transistor, the epitaxial layers 40 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 40 are preferred to have less or no germanium atom at all to facilitate the formation of silicide afterwards.

According to an embodiment of the present invention, it would also be desirable to form source/drain regions 42 in part or all of the epitaxial layers 40. According to another embodiment of the present invention, the source/drain regions 42 could also be formed insituly during the SEG process. For instance, the source/drain regions 42 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain regions 42. Moreover, the dopants within the source/drain regions 42 could also be formed with a gradient, which is also within the scope of the present invention.

Next, as shown in FIG. 6, an interlayer dielectric (ILD) layer 44 made of silicon oxide is formed on the gate structures 32, 34 and isolation structures 22, 24, and a planarizing process such as chemical mechanical polishing (CMP) process is conducted to remove part of the ILD layer 44 for exposing the gate material layers 36 so that the top surfaces of the gate material layers 36 and the ILD layer 44 are coplanar.

Next, a replacement metal gate (RMG) process is conducted to transform the gate structures 32, 34 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layers 36 from gate structures 32, 34 for forming recesses 46 in the ILD layer 44. Since the width of the aforementioned gate structure 32 on the non-planar device region 14 is substantially less than the width of the gate structure 34 on the planar device region 16, the width of the recess 46 on the non-planar device region 14 would also be less than the width of the recess 46 on the planar devices region 16 after the gate material layers 36 are removed.

Next, as shown in FIG. 7, an etching process is conducted to remove the gate dielectric layer 30 on the non-planar device region 14 and then a thermal oxidation process is conducted to form an interfacial layer 48 or another gate dielectric layer made of silicon oxide on the surface of the fin-shaped structures 20 adjacent to two sides of the isolation structure 22 on the non-planar device region 14 and the substrate 12 adjacent to two sides of the isolation structure 24 on the planar device region 16. It should be noted that part of the isolation structure 22 could be removed at the same time during removal of the gate dielectric layer 30 on the non-planar device region 14 and after the interfacial layer 48 is formed, only the interfacial layer 48 is disposed in the recess 46 on the non-planar device region 14 while both the gate dielectric layer 30 and interfacial layer 48 are disposed in the recess 46 on the planar device region 16. Preferably, the thickness of the interfacial layer 48 on the non-planar device region 14 is between 5-9 Angstroms or most preferably 7 Angstroms while the gate dielectric layer 30 and interfacial layer 48 on the planar device region 16 are combined to form a new interfacial layer 50 or gate dielectric layer made of silicon oxide, in which the thickness of the interfacial layer 50 is between 30-40 Angstroms or most preferably 35 Angstroms.

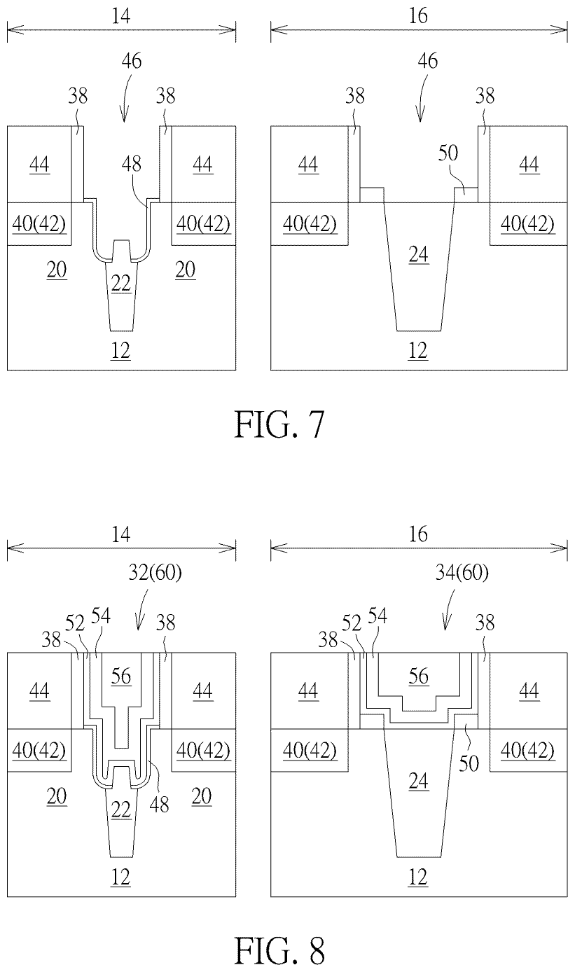

Next, as shown in FIG. 8, a high-k dielectric layer 52, a work function metal layer 54, and a low resistance metal layer 56 are formed in the recesses, and a planarizing process such as CMP is conducted to remove part of low resistance metal layer 56, part of work function metal layer 54, and part of the high-k dielectric layer 52 so that the top surfaces of the U-shape high-k dielectric layer 52, the U-shape work function metal layer 54, the low resistance metal layer 56, and the ILD layer 44 are coplanar. Preferably, the high-k dielectric layer 52, the work function metal layer 54, and the low resistance metal layer 56 altogether constitute a gate electrode for each of the transistors or devices.

In this embodiment, the high-k dielectric layer 52 is preferably selected from dielectric materials having dielectric constant (k value) larger than 4. For instance, the high-k dielectric layer 42 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 54 is formed for tuning the work function of the metal gate in accordance with the conductivity of the device. For an NMOS transistor, the work function metal layer 54 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 54 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 54 and the low resistance metal layer 56 may include titanium (Ti), titanium nitride (TiN), tantalum (Ta) or tantalum nitride (TaN). Furthermore, the material of the low-resistance metal layer 56 may include copper (Cu), aluminum (Al), titanium aluminum (TiAl), cobalt tungsten phosphide (CoWP) or any combination thereof. Since the transformation of dummy gates into metal gates through RMG process is well known to those skilled in the art, the details of which are not explained herein for the sake of brevity. Next, contact plugs connecting the epitaxial layers 40 and/or source/drain regions 42 could be formed depending on the demand of the product. This completes the fabrication of a semiconductor device according to a preferred embodiment of the present invention.

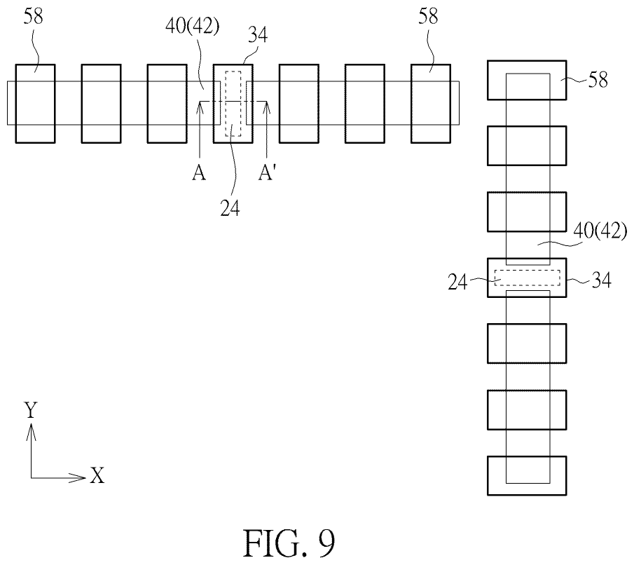

Referring to FIGS. 8-9, FIG. 8 illustrates a structural view of a semiconductor device according to an embodiment of the present invention and FIG. 9 illustrates a top view of the semiconductor device on the planar device region according to an embodiment of the present invention, in which the right portion of FIG. 8 further illustrates a cross-section of FIG. 9 taken along the sectional line AA′. As shown in FIGS. 8-9, the semiconductor device includes a non-planar device region 14 and a planar device region 16 defined on the substrate 12, an isolation structure 22 disposed in the fin-shaped structures 20 on the non-planar device region 14, a gate structures 32 disposed on the isolation structure 22, epitaxial layers 40 adjacent to two sides of the gate structure 32, an isolation structure 24 disposed in the substrate 12 on the planar device region 14, a gate structure 34 disposed on the isolation structure 24, and epitaxial layers 40 adjacent to the gate structure 34. Preferably, each of the gate structures 32, 34 include a metal gate.

Specifically, the top surface of the isolation structure 22 is lower than the top surface of the isolation structure 24, the bottom surface of the gate structure 32 is lower than the bottom surface of the gate structure 34, the width of the gate structure 32 is less than the width of the gate structure 34, the gate structure 32 overall includes an I-shape cross-section, and the gate structure 34 overall includes a T-shape cross-section. Preferably, each of the I-shape cross-section from the gate structure 32 and the T-shape cross-section from the gate structure 34 includes either one or any cross-section combinations of the high-k dielectric layer 52, the work function metal layer 54, and the low resistance metal layer 56. For instance, the bottom surface of the T-shape cross-section of the gate structure 34 made of high-k dielectric layer 52, the work function metal layer 54, and/or the low resistance metal layer 56 is even with or slightly higher than the surface of the substrate 12 on two adjacent sides. Moreover, the interfacial layer 48 on the non-planar device region 14 is extending from the top surface and sidewalls of the fin-shaped structures 20 to the surface of the isolation structure 22, the interfacial layer 50 on the planar device region 16 is disposed on the surface of the substrate 12 adjacent to two sides of the isolation structure 24, and sidewalls of the interfacial layers 48, 50 on each region are aligned with sidewalls of each of the gate structures 32, 34.

As shown in FIG. 9, a single gate structure 34 is disposed directly on top of the isolation structure 24, the gate structure 34 is disposed to cover the isolation structure 24 entirely, and the gate structure 24 and adjacent gate structures 58 are fabricated from the same process thereby having same structure compositions. It should also be noted that the gate structures 34, 58, the isolation structures 24, and epitaxial layers 40 not only extending along the X-direction, but could also extend other directions such as Y-direction, which are all within the scope of the present invention.

Overall, the present invention discloses an approach of forming isolation structures or SDB structures on non-planar device region and planar device region at the same time and then forming a single gate structure directly on the isolation structure of each region. Preferably, the top surface of the isolation structure 22 on the non-planar device region is slightly lower than the top surface of the isolation structure 24 on the planar device region, the width of the isolation structure on the non-planar device region is less than the width of the isolation structure on the planar device region, the width of the gate structure 32 on the non-planar device region is less than the width of the gate structure 34 on the planar device region, and top surfaces of the gate structures 32, 34 on each region are coplanar. According to a preferred embodiment of the present invention, by forming isolation structures each having a single gate structure atop on the non-planar device region as well as forming isolation structures each having a single gate structure atop on the planar device region, overall area of the device could be reduced effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having a non-planar device region and a planar device region;
forming a first isolation structure in the substrate of the planar device region;
forming a first gate structure on the first isolation structure;
forming an interlayer dielectric (ILD) layer around the first gate structure; and
transforming the first gate structure into a first metal gate.

2. The method of claim 1, further comprising:
forming a second isolation structure in the substrate of the non-planar device region;
removing part of the second isolation structure;
forming a first gate dielectric layer on the substrate of the non-planar device region and the planar device region;
forming the first gate structure on the first isolation structure and a second gate structure on the second isolation structure;
forming a first epitaxial layer adjacent to the first gate structure and a second epitaxial layer adjacent to the second gate structure;
forming the ILD layer around the first gate structure and the second gate structure;
removing the first gate structure and the second gate structure to form a first recess and a second recess;
forming a second gate dielectric layer in first recess and the second recess; and
forming the first metal gate in the first recess and a second metal gate in the second recess.

3. The method of claim 2, further comprising forming the first gate structure on the first isolation structure and the first gate dielectric layer on the planar device region.

4. The method of claim 2, further comprising forming the second gate structure on the second isolation structure and the first gate dielectric layer on the non-planar device region.

5. The method of claim 2, wherein a top surface of the second isolation structure is lower than a top surface of the first isolation structure.

6. The method of claim 2, wherein a bottom surface of the second metal gate is lower than a bottom surface of the first metal gate.

7. The method of claim 2, wherein a width of the second metal gate is less than a width of the first metal gate.

8. The method of claim 2, wherein the second metal gate comprises an I-shape.

9. The method of claim 1, wherein the first metal gate comprises a T-shape.

10. A semiconductor device, comprising:
a substrate having a non-planar device region and a planar device region;
a first isolation structure in the substrate of the planar device region;
a first gate structure on the first isolation structure; and
a first epitaxial layer adjacent to the first gate structure.

11. The semiconductor device of claim 10, further comprising:
a second isolation structure in the substrate of the non-planar device region;
a second gate structure on the second isolation structure; and
a second epitaxial layer adjacent to the second gate structure.

12. The semiconductor device of claim 11, wherein the first gate structure comprises a first metal gate and the second gate structure comprises a second metal gate.

13. The semiconductor device of claim 12, wherein a top surface of the second isolation structure is lower than a top surface of the first isolation structure.

14. The semiconductor device of claim 12, wherein a bottom surface of the second metal gate is lower than a bottom surface of the first metal gate.

15. The semiconductor device of claim 12, wherein a width of the second metal gate is less than a width of the first metal gate.

16. The semiconductor device of claim 12, wherein the second metal gate comprises an I-shape.

17. The semiconductor device of claim 12, wherein the first metal gate comprises a T-shape.
